(19) United States
(12) Patent Application Publication
(10) Pub. No.: US 2016/0314852 A1
(43) Pub. Date: Oct. 27, 2016

(54) SYSTEM AND METHOD OF MEMORY MANAGEMENT

(71) Applicant: Hermes Testing Solutions Inc., Hsinchu City (TW)

(72) Inventors: Shih-Hsin CHEN, Hsin-Chu City (TW); Shih-Chieh JANG, Longtan Township (TW); Bosco Chun Sang LAI, Ontario (CA)

(21) Appl. No.: 14/693,453

(22) Filed: Apr. 22, 2015

(51) Int. Cl. G11C 29/44; G11C 29/38

(52) U.S. Cl. CPC G11C 29/44; G11C 29/38

(57) ABSTRACT

Embodiments of system and methods for managing memory cells are disclosed, where a memory priority map is generated based on at least one testing procedure, and memory cells of a memory device are allocated to at least one application executed in a computing system by the memory priority map and defined allocating regulations. Further, whenever a fresh memory testing procedure is executed, the memory priority map is updated.

### BACKGROUND OF THE INVENTION

1. Field of the Invention

The present invention relates to a system and a method of memory management, particularly to a system and a method for allocating memory cells to an application based on the memory quality levels.

2. Description of the Prior Art

A computing system typically employs storage media such as random access memory (RAM). As memory size increases, the probability of memory cells of memory devices either being manufactured defective or becoming defective during their deployment increases significantly. Correspondingly, the defective memory cells may cause the computing system to fail. This failure can potentially cause a “crash” which means a termination in the current functioning of the computing system. This may result in the loss of critical information.

Regarding the issue of defective memory cells, variety methods for testing/scanning/detecting memory device have been presented. Such testing methods comprise testing a memory device in a computing system or out of a computing system to detect errors or defects existing in the memory device. Some methods further present that when finding defective memory cells in a memory device, a corresponding means is provided to record physical addresses of defective memory cells or memory locations, and the recorded defective memory cells may be isolated from being accessible for any application executable in a computing system, remedied by a specific means, or substituted by redundant memory cells.

Wherein, most of the conventional methods simply classify memory cells into two levels. In one level, memory cells without any error or having minor error are available for an application; in the other level, defective memory cells are not available for an application. However, such dichotomous classification decreases the utilization efficiency of a memory device, when memory cells are simply divided into good/available and bad/unavailable levels.

Reference to U.S. patent publication No. 2014/0068360 titled “System and Methods for Testing Memory”, Lai et al. mainly presents a testing method for detecting and verifying errors for memory cells and further mention a concept for ranking each memory cell quality/grade based on detecting error times of individual memory cell. However, U.S. patent publication No. 2014/0068360 no further disclose nor suggest how to manage those memory cells with different levels, but yet deny the accessibility for memory cells which are judged and verified as defective. That is to say, the ranking levels of memory cells mentioned in U.S. patent publication No. 2014/0068360 have no substantial contribution to memory management. Nevertheless, U.S. patent publication No. 2014/0068360, disclosing relating backgrounds and knowledge of correlating hardware for testing memory devices, is incorporated in the present invention for reference but not limited other memory testing methods, apparatuses, or systems applied to the present invention.

### SUMMARY OF THE INVENTION

To solve the lower utilization efficiency of memory devices as mentioned above, the present invention provides a method for managing memory cells, wherein memory cells are ranked based on their qualities and correspondingly allocated to at least one application in an order following their rank grades.

In one broad aspect, there is provided a method for managing a memory device, wherein the memory device comprises a plurality of memory cells and is utilized in a computing system. During at least one memory testing procedure, at least one of the plurality of memory cells is tested to form a tested memory cell. The tested memory cell has a number of error times. The number of error times comprises a total number of error times which records the times that the tested memory cell is detected as defective. The method comprises providing a tested memory allocating regulation. The tested memory allocating regulation defines that when the total number of error times of the tested memory cell is higher, the priority for allocating the corresponding tested memory cell to an application executed in the computing system is lower.

Preferably, a preset number of discontinuous error times is provided and at least two. The number of error times further comprises a number of discontinuous error times. The number of discontinuous error times is counted according to a defect detecting situation which defines that the number of discontinuous error times is accumulatively counted only when the tested memory cell is detected as defective in continuous testing procedures; if the tested memory is not detected in one testing procedure, the number of discontinuous error times is reset to zero. The tested memory allocating regulation further defines that when the number of discontinuous error times of the tested memory cell exceeds the preset number of discontinuous error times, the corresponding tested memory cell is not allowed to be allocated to any application executed in the computing system.

In another broad aspect, there is provided a system for managing a memory device, and the system comprises a computing system. The computing system comprises at least one physical processor, a non-transient memory device and instructions. At least one application is executable by the at least one processor. The non-transient memory device comprises a plurality of memory cells and utilized in the computing system. During at least one memory testing procedure, at least one of the plurality of memory cells is tested to form a tested memory cell. The tested memory cell has a number of error times. The number of error times comprises a total number of error times which records the times that the tested memory cell is detected as defective. When the instructions are executed by the at least one processor, the instructions configured the at least one processor to follow a tested memory allocating regulation to allocate tested memory cells to the at least one application. The tested memory allocating regulation defines that when the total number of error times of the tested memory cell is higher, the priority for allocating the corresponding tested memory cell to the at least one application is lower.

Preferably, a preset number of discontinuous error times is provided and at least two. The number of error times further comprises a number of discontinuous error times. The number of discontinuous error times is counted according to a defect detecting situation which defines that the number of discontinuous error times is accumulatively counted only when the tested memory cell is detected as defective in successive testing procedures; if the tested memory is not detected in one testing procedure, the number of discontinuous error times is reset to zero. The tested memory allocating regulation further defines that when the number of discontinuous error times of the tested memory cell exceeds the preset number of discontinuous error times, the corresponding tested memory cell is not allowed to be allocated to any application.

In further another broad aspect, there is provided a non-transient computer-readable medium comprising instructions for allocating at least one tested memory cell of a memory device within a computing system. At least one application is executable in the computing system. The memory device comprising a plurality of memory cells and utilized in the computing system. During at least one memory testing procedure, at least one of the plurality of memory cells is tested to form a tested memory cell. The tested memory cell has a number of error times. The number of error times comprises a total number of error times which records the times that the tested memory cell is detected as defective. When the instructions are executed by at least one processor of the computing system, the instructions configure the at least one processor to follow a tested memory allocating regulation to allocate tested memory cells to the at least one application. The tested memory allocating regulation defines that when the total number of error times of the tested memory cell is higher, the priority for allocating the corresponding tested memory cell to the at least one application.

Preferably, a preset number of discontinuous error times is provided and at least two. The number of error times further comprises a number of discontinuous error times. The number of discontinuous error times is counted according to a defect detecting situation which defines that the number of discontinuous error times is accumulatively counted only when the tested memory cell is detected as defective in successive testing procedures; if the tested memory is not detected in one testing procedure, the number of discontinuous error times is reset to zero. The tested memory allocating regulation further defines that when the number of discontinuous error times of the tested memory cell exceeds the preset number of discontinuous error times, the corresponding tested memory cell is not allowed to be allocated to any application.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a flow diagram illustrating acts of a method for managing memory cells of a memory device in accordance with at least one embodiment; and

FIG. 2 is a flow diagram based on FIG. 1 for illustrating the updating iteration of the memory priority map in accordance with at least one embodiment.

### DESCRIPTION OF THE PREFERRED EMBODIMENT

The detailed explanation of the present invention is described as follows. The described preferred embodiments and examples are presented for purposes of illustrations and description, and they are not intended to limit the scope of the present invention.

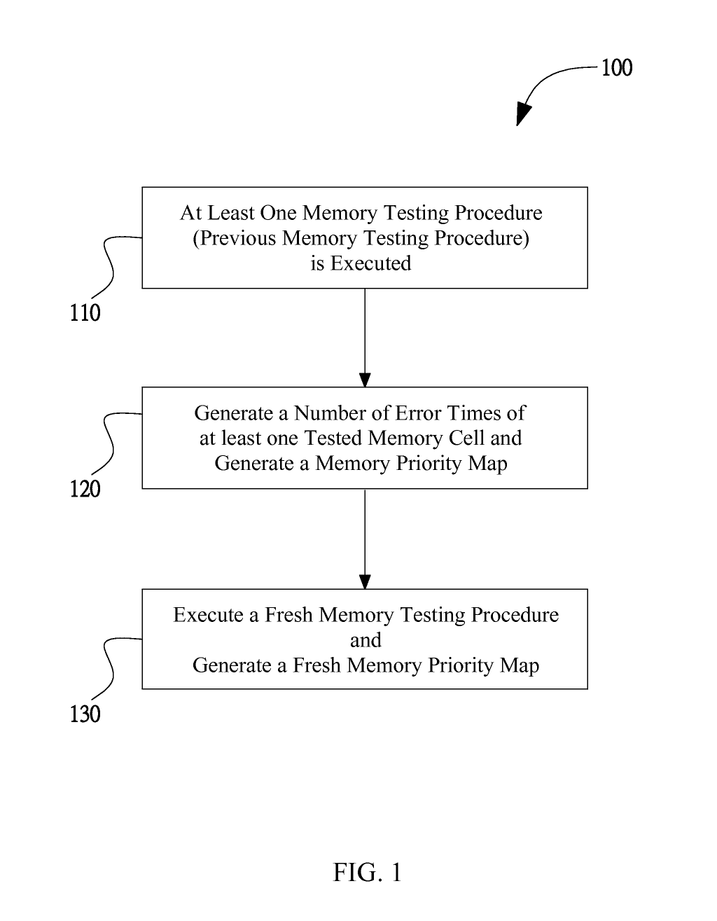

Referring to FIG. 1, a flow diagram illustrating steps of a method for managing memory cells of a memory device in accordance with at least one embodiment is shown generally as 100. Wherein, the memory device comprises a plurality of memory cells and is utilized in a computing system.

More specifically, the computing system is referred as a computer with at least one physical processor therein. The memory device is a non-transient readable and storable memory. The memory cell may comprise at least one memory location which is a minimum addressable unit for allocating to at least one application executed in the computing system. It will be understood by persons skilled in the art that the variety types and examples of the terms “computing system”, “processor”, “memory device”, “memory cell” and “memory location”.

In step 110, the memory device had been tested or is just tested by at least one memory testing procedure. During the at least one memory testing procedure, at least one of the plurality of memory cells is tested to form a tested memory cell, and the others of the plurality of memory cells which are not tested are defined as untested memory cells. Wherein, during one memory testing procedure, the tested memory cell may be detected as error or defective, and a corresponding number of error times of the tested memory cell is counted/recorded and generated accordingly. That is to say, the tested memory cell has a corresponding number of error times which records the times that the tested memory cell is detected as defective in the at least one procedure.

Preferably, each corresponding number of error times of each tested memory cell is counted in an accumulating way in every memory testing procedures, so that the number of error times of the tested memory cell can be referred as an indicator of quality of the tested memory cell. For example, during multiple memory testing procedures, a low quality memory cell is most possibly detected as defective in each of or in most of the memory testing procedures; a medium quality memory cell may be detected as defective in some of the memory testing procedures; a high quality memory cell may be detected as defective only in few of or even in none of the memory testing procedures. In other words, in one memory testing procedure, a low quality memory cell has a high possibility for being detected as defective; a medium quality memory cell has a moderate possibility for being detected as defective; a high quality memory has a low possibility for being detected as defective.

More specifically, the number of error times comprises a total number of error times and an optional number of discontinuous error times. The total number of error times of the tested memory cell is accumulatively counted when the tested memory cell is detected as defective. The number of discontinuous error times is counted according to a defect detecting situation which defines that the number of discontinuous error times is accumulatively counted only when the tested memory cell is detected as defective in successive testing procedures; and if the tested memory is not detected in one testing procedure, the number of discontinuous error times is reset to zero. To elaborate more explicitly, following Table 1 shows the differences between the total number and the number of discontinuous error times.

Wherein, the at least one memory testing procedure in step 110 may be proceeded within or out of the computing system. In one example, when the at least one memory testing procedure is proceeded in the computing system, the at least one memory testing procedure may be executed in one of the timings when system is powering up, working, idling and powering off.

TABLE 1

| | Testing Procedure | | | | | | | |
|---|---|---|---|---|---|---|---|---|
| | 1^{st} | 2^{nd} | 3rd | 4nd | 5nd | 6nd | 7nd | 8nd |
| Error Detected? | N | Y | Y | N | Y | Y | Y | Y |
| Total Number | 0 | 1 | 2 | 2 | 3 | 4 | 5 | 6 |
| of Error Times | | | | | | | | |
| Number of | 0 | 1 | 2 | 0 | 1 | 2 | 3 | 4 |
| discontinuous error | | | | | | | | |
| Times | | | | | | | | |
| Maximum Number | 0 | 1 | 2 | 2 | 2 | 2 | 3 | 4 |
| of discontinuous | | | | | | | | |
| error times | | | | | | | | |

In step 120, a tested memory allocating regulation is provided that the lower quality of the tested memory cell is, the lower priority for allocating the corresponding tested memory cell is. That is to say, when the total number of error times of the testes memory cell is higher, the priority for allocating the corresponding tested memory cell to an application executed in the computing system is lower. In accordance to the above-mentioned tested memory allocating regulation, a memory priority map comprising an accessible tested memory list is generated. When a corresponding total number of error times of a tested memory cell is at least one, the information of physical address and the corresponding number of error times of the tested memory cell is classified to and recorded in the accessible tested memory list.

Preferably, in an optional example, a preset number of discontinuous error times is provided and is at least one. Wherein, the tested memory allocating regulation further defines that the tested memory cell, having the maximum number of discontinuous error times exceeding the preset number of discontinuous error time, is not allowed to be allocated to an application executed in the computing system. In accordance to the above-mentioned tested memory allocating regulation, a memory priority map comprising an accessible tested memory list and a non-accessible tested memory list is generated. When a corresponding total number of error times of a tested memory cell is at least one and a corresponding maximum number of discontinuous error times of the tested memory cell is not greater than the preset number of discontinuous error times, the information of physical address and the corresponding number of error times of the tested memory cell is classified to and recorded in the accessible tested memory list. When a corresponding maximum number of discontinuous error times of a tested memory cell exceeds the preset number of discontinuous error times, the information of physical address and the corresponding number of error times of the tested memory cell is classified to and recorded in the non-accessible tested memory list. In one preferred example, the preset number of discontinuous error times is at least three. In another preferred example, the preset number of discontinuous error times is at least five. Optionally, the preset number of discontinuous error times is manually adjusted by a user and is at least one.

Based on the above-mentioned quality classification and allocation for tested memory cells in the memory priority map and the tested memory allocating regulation, the chance on allocating low quality tested memory cells to an application is decreased, and the lowest quality tested memory cells, which have number of discontinuous error times exceeding the preset number of discontinuous error times, are prohibited/prevented from being accessible by any application executed in the computing system, so that the potential causing crash to the computing system is accordingly decreased.

Preferably, in an optional step 130, a fresh/new memory testing procedure is executed to generate a fresh memory priority map. The fresh memory testing procedure is a latest memory testing procedure different from the at least one/previous memory testing procedure or is a continuous procedure of the previous memory testing procedure. The others of the plurality memory cells which are not tested in the at least one memory testing are defined as untested memory cells. By executing the fresh memory testing procedure, at least one of the tested memory cells and the untested memory cells is tested to form a tested memory cell, and the total or number of discontinuous error times of the tested memory cell is counted so as to update the latest information of the total or number of discontinuous error times of the tested memory cell. More specifically, the total number of error times of the tested memory cell is accumulatively counted as the tested memory is detected as defective. The number of discontinuous error times is accumulatively counted or reset as zero in accordance with the defect detected situation of the corresponding tested memory cell. Based on the update of the number of error times, the memory priority map comprising the accessible tested memory list and the optional non-accessible tested memory list are updated correspondingly to the fresh memory priority map. That is to say, in the fresh memory priority map, latest information of the number of error times of tested memory cells is correspondingly recorded. Hence, memory cells of the computing system will be much more properly applied based on the fresh memory priority map and the tested memory allocating regulation.

Based on the above-mentioned fresh memory testing procedure, an up-to-date condition of the memory cell is detected, so that a latest condition of the memory device is surveilled/monitored, and a fresh memory priority map is generated/obtained. Therefore, the memory cells in the memory device will be well allocated to an application by following the tested memory allocating regulation.

It shall be noted that the terms “previous”, “fresh”, “new”, “latest”, “updated” and the like are utilized to describe timing sequences of the generation of memory priority map. To elaborate more explicitly, successive examples are presented as following contents and Tables 2-4.

Table 2 is an example for showing a statistics of memory priority map, wherein a first testing procedure is executed and is referred as the at least one memory testing procedure in step 110. Wherein, the tested memory cells with the memory cell addresses “001” and “002” are detected as defective during the first testing procedure, so that each of the memory cell addresses “001” and “002” comprises the information of the total number of error times representing one and the number of discontinuous error times representing one, and is stored in the accessible tested memory list. The tested memory cells with the memory cell addresses “003”, “004” and “005” are tested and detected without error during the first testing procedure, so that each of the memory cell addresses “003”, “004” and “005” comprises the information of the total number of error times representing zero and the number of discontinuous error times representing zero, and is not stored in the accessible tested memory list. The untested memory cell with the memory cell address “006” is not tested during the first testing procedure, and hence has no corresponding record on the total number of error times representing zero and the number of discontinuous error times.

TABLE 2

| | Memory Cell Address | | | | | |
|---|---|---|---|---|---|---|
| | 001 | 002 | 003 | 004 | 005 | 006 |
| First Testing Procedure | Y | Y | N | N | N | — |
| (Error Detected?) | | | | | | |
| Total Number of | 1 | 1 | 0 | 0 | 0 | — |
| Error Times | | | | | | |
| Number of discontinuous | 1 | 1 | 0 | 0 | 0 | — |
| error Times | | | | | | |
| Stored in the Accessible | Y | Y | N | N | N | N |
| Tested Memory List? | | | | | | |
| Stored in the | N | N | N | N | N | N |
| Non-accessible Tested | | | | | | |
| Memory List? | | | | | | |

Other conditions:
1. The preset number of discontinuous error times is 2.
2. When the number of discontinuous error times is greater than 2, the corresponding tested memory cell is prohibited from being utilized.

TABLE 3

| | Memory Cell Address | | | | | |
|---|---|---|---|---|---|---|
| | 001 | 002 | 003 | 004 | 005 | 006 |
| First Testing Procedure | Y | Y | N | N | N | — |
| (Error Detected?) | | | | | | |
| Second Testing Procedure | Y | N | Y | N | N | — |
| (Error Detected?) | | | | | | |
| Total Number of | 2 | 1 | 1 | 0 | 0 | — |
| Error Times | | | | | | |
| Number of discontinuous | 2 | 0 | 1 | 0 | 0 | — |
| error Times | | | | | | |
| Stored in the Accessible | Y | Y | Y | N | N | N |
| Tested Memory List? | | | | | | |
| Stored in the | N | N | N | N | N | N |
| Non-accessible Tested | | | | | | |
| Memory List? | | | | | | |

Other conditions:
1. The preset number of discontinuous error times is 2.
2. When the number of discontinuous error times is greater than 2, the corresponding tested memory cell is prohibited from being utilized.

TABLE 4

| | Memory Cell Address | | | | | |
|---|---|---|---|---|---|---|
| | 001 | 002 | 003 | 004 | 005 | 006 |
| 1st Testing Procedure | Y | Y | N | N | N | — |
| (Error Detected?) | | | | | | |
| 2nd Testing Procedure | Y | N | Y | N | N | — |
| (Error Detected?) | | | | | | |
| 3rd Testing Procedure | Y | Y | Y | Y | N | N |
| (Error Detected?) | | | | | | |
| Total Number of | 3 | 2 | 2 | 1 | 0 | 0 |
| Error Times | | | | | | |
| Number of discontinuous | 3 | 1 | 2 | 1 | 0 | 0 |
| error Times | | | | | | |
| Stored in the Accessible | N | Y | Y | Y | N | N |
| Tested Memory List? | | | | | | |
| Stored in the | Y | N | N | N | N | N |
| Non-accessible Tested | | | | | | |
| Memory List? | | | | | | |

Other conditions:
1. The preset number of discontinuous error times is 2.
2. When the number of discontinuous error times is greater than 2, the corresponding tested memory cell is prohibited from being utilized.

In a continuous example to Table 2, the following Table 3 shows an updating statistics of memory priority map, wherein the first testing procedure is referred as the at least one memory testing procedure in step 110 (previous memory testing procedure), and a second testing procedure is referred as a fresh memory testing procedure in step 130. In this example of Table 3, an updating number of error times and an updating memory priority map is obtained and will be utilized for allocating tested memory cells. Wherein, the tested memory cell with the memory cell address “001” is detected as defective in each of the first and second testing procedures, so that the memory address “001” comprises the information of the total number of error times representing two and the number of discontinuous error times representing two, and is still stored in the accessible tested memory list. The tested memory cell with the memory cell address “002” is detected without error in the second testing procedure, so that the total number of error times thereof is one and the number of discontinuous error times thereof is zero, and the corresponding information is stored in the accessible tested memory list. The tested memory cell with the memory cell address “003” is detected as defective in the second testing procedure, so that each of the total number of error times and the number of discontinuous error times thereof is one, and the corresponding information is stored in the accessible tested memory list. The memory cells with the memory cell addresses “004” and “005” are tested and detected without error during the first and second testing procedure, so that each of the memory cell addresses “004” and “005” comprises the information of the total number of error times representing zero and the number of discontinuous error times representing zero, and is not stored in the accessible tested memory list. The memory cell with the memory cell address “006” is not tested during the first and second testing procedure.

In a continuous example to Table 3, the following Table 4 shows an updating statistics of memory priority map, wherein the first and second testing procedures are referred as the at least one memory testing procedure in step 110 (previous memory testing procedure(s)), and a third testing procedure is referred as a fresh memory testing procedure in step 130. In this example of Table 4, an updating number of error times and an updating memory priority map is obtained and will be utilized for allocating tested memory cells. Wherein, the tested memory cell with the memory cell addresses “001” is detected as defective in every of the first, second and third testing procedures, so that the memory address “001” comprises the information of the total number of error times representing three and the number of discontinuous error times representing three. Because the number of discontinuous error times is greater than the preset number of discontinuous error times assigned as two, the corresponding information of the tested memory cell with memory address “001” is classified and stored in the non-accessible memory list. The tested memory cell with the memory cell address “002” is detected as defective in the first and third testing procedures, so that the total number of error times thereof is two and the number of discontinuous error times thereof is one, and the corresponding information is stored in the accessible tested memory list. The tested memory cell with the memory cell address “003” is detected as defective in the second and third testing procedures, so that each of the total number of error times and the number of discontinuous error times thereof is two, and the corresponding information is stored in the accessible tested memory list. The memory cell with the memory cell address “004” is detected as defective during the third testing procedure, so that each of the total number of error times and the number of discontinuous error times thereof is one, and the corresponding information is stored in the accessible tested memory list. The memory cell with the memory cell address “005” is tested without any error during the first, second and third testing procedures, so that each of the total number of error times and the number of discontinuous error times thereof is zero, and the corresponding information is not stored in the accessible tested memory list. The memory cell with the memory cell address “006” is firstly tested in the third testing procedures and no error is detected, so that each of the total number of error times and the number of discontinuous error times thereof is zero, and the corresponding information is not stored in the accessible tested memory list.

It shall be noted that the situation that memory cells are tested one time in every above-mentioned testing procedure is used to explain how the updating of the number of error times, the tested memory priority map and the sequent fresh tested memory priority maps are generated, but not used to be a limitation to the invention; wherein, in some real cases, a memory cell may be tested many times or detected as defective more than one time in one testing procedure.

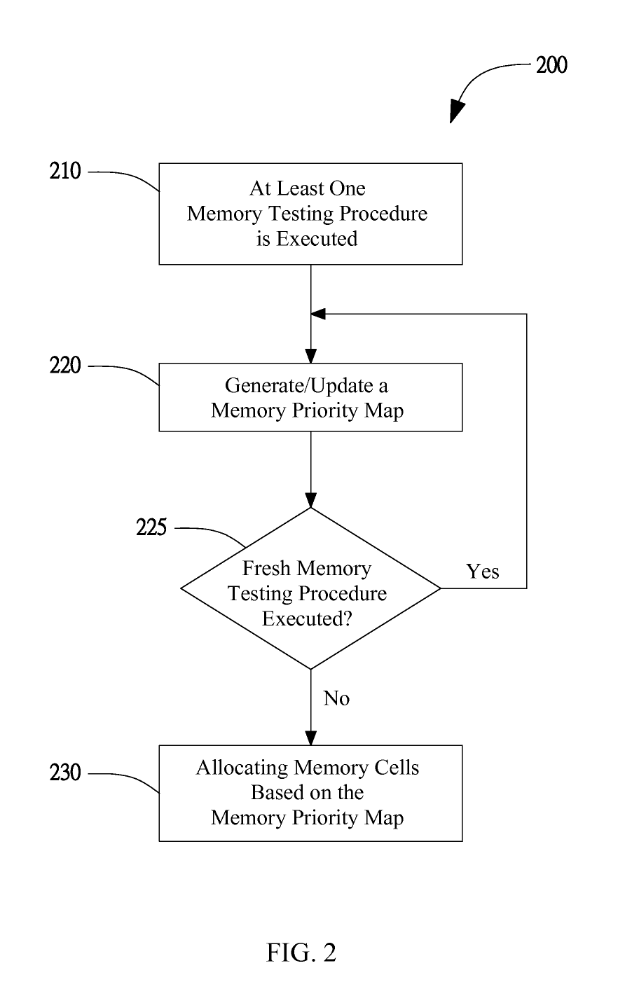

Based on all above-mentioned contents, FIG. 2 shows a flow diagram illustrating a memory management process in accordance with at least one embodiment is shown generally as 200. In step 210, at least one memory testing procedure is executed, and the corresponding number of error times of at least one memory cell is counted and recorded. In step 220, a memory priority map is generated based on the information from step 210. In step 225, it is determined whether any latest memory testing procedure, which is defined as the fresh memory testing procedure, is executed. If no fresh memory testing procedure is executed, the memory priority map, derived from step 210, has the latest information about memory condition for memory management to the computing system in step 230. If a fresh memory testing procedure is executed, the memory priority map is updated in accordance with the latest information derived from the execution of the fresh memory testing procedure in step 220, and memory cells will be managed based on the latest information derived from the execution of the fresh memory testing procedure in step 230. Therefore, memory cells of a memory device of this embodiment of the present invention is ensured to be optimally utilized based on the latest fresh memory priority map and the above-mention relating allocation regulations defined in the foregoing embodiments of the present invention.

Acts of one or more of the methods described herein may be embodied as computer-readable instructions, stored in a non-transient computer-readable medium, for example. Wherein, said computer readable instructions are executed by a processor within a computing system, so that the processor is configured to perform the one or more of the foregoing methods herein. Further, a system for memory management may be embodied by a computing system which carried out said instructions.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A method of managing a memory device, wherein the memory device comprises a plurality of memory cells and is utilized in a computing system; wherein during at least one memory testing procedure, at least one of the plurality of memory cells is tested to form a tested memory cell, the tested memory cell has a number of error times, the number of error times comprises a total number of error times which records the times that the tested memory cell is detected as defective; and the method comprises: providing a tested memory allocating regulation; wherein the tested memory allocating regulation defines that when the total number of error times of the tested memory cell is higher, the priority for allocating the corresponding tested memory cell to an application executed in the computing system is lower.

2. The method of claim 1, further comprising generating a memory priority map; wherein the memory priority map comprises an accessible tested memory list, when the total number of error times of the tested memory cell is at least one, the information of a physical address and the number of error times of the corresponding tested memory cell is classified to and recorded in the accessible tested memory list.

3. The method of claim 1, further comprising performing a fresh memory testing procedure on the memory device; wherein the others of the plurality of memory cells which are not tested in the at least one memory testing procedure are defined as untested memory cells; during the fresh memory testing procedure, at least one of the tested memory cells and the untested memory cells is tested; when a untested memory cell is tested, the untested memory cell becomes a tested memory cell; and the total number of error times of the tested memory cell is accumulatively counted as the tested memory is detected as defective.

4. The method of claim 1, wherein a preset number of discontinuous error times is provided and at least two, the number of error times further comprises a number of discontinuous error times, the number of discontinuous error times is counted according to a defect detecting situation which defines that the number of discontinuous error times is accumulatively counted only when the tested memory cell is detected as defective in successive testing procedures; if the tested memory is not detected in one testing procedure, the number of discontinuous error times is reset to zero; and the tested memory allocating regulation further defines that when the number of discontinuous error times of the tested memory cell exceeds the preset number of discontinuous error times, the corresponding tested memory cell is not allowed to be allocated to any application executed in the computing system.

5. The method of claim 4, wherein the preset number of discontinuous error times is at least three.

6. The method of claim 4, wherein the preset number of discontinuous error times is at least five.

7. The method of claim 4, wherein the preset number of discontinuous error times is manually adjusted by a user.

8. The method of claim 4, further comprising generating a memory priority map; wherein the memory priority map comprises an accessible tested memory list and a non-accessible tested memory list; wherein when the total number of error times of the tested memory cell is at least one, and when the maximum number of discontinuous error times of the tested memory cell is not greater than the preset number of discontinuous error times, the information of a physical address and the number of error times of the corresponding tested memory cell are recorded in the accessible tested memory list; wherein when the number of discontinuous error times of the tested memory cell exceeds the preset number of discontinuous error times, the information of physical address and the corresponding number of error times of the tested memory cell is classified to and recorded in the non-accessible tested memory list.

9. The method of claim 8, wherein the preset number of discontinuous error times is at least three.

10. The method of claim 8, wherein the preset number of discontinuous error times is at least five.

11. The method of claim 8, wherein the preset number of discontinuous error times is manually adjusted by a user.

12. The method of claim 4, further comprising performing a fresh memory testing procedure on the memory device; wherein the others of the plurality of memory cells which are not tested in the at least one memory testing procedure are defined as untested memory cells; during the fresh memory testing procedure, at least one of the tested memory cells and the untested memory cells is tested; when a untested memory cell is tested, the untested memory cell becomes a tested memory cell; the total number of error times of the tested memory cell is accumulatively counted as the tested memory is detected as defective, and the number of discontinuous error times is accumulatively counted or reset as zero in accordance with the defect detecting situation of the corresponding tested memory cell.

13. The method of claim 8, wherein the preset number of discontinuous error times is at least three.

14. The method of claim 8, wherein the preset number of discontinuous error times is at least five.

15. The method of claim 8, wherein the preset number of discontinuous error times is manually adjusted by a user.

16. A system of managing a memory device, comprising:
a computing system comprising:
at least one physical processor, wherein at least one application is executable by the at least one processor;
a non-transient memory device comprising a plurality of memory cells and utilized in the computing system; wherein during at least one memory testing procedure, at least one of the plurality of memory cells is tested to form a tested memory cell, the tested memory cell has a number of error times, the number of error times comprises a total number of error times which records the times that the tested memory cell is detected as defective; and
instructions when executed by the at least one processor, configured the at least one processor to:
follow a tested memory allocating regulation to allocate tested memory cells to the at least one application; wherein the tested memory allocating regulation defines that when the total number of error times of the tested memory cell is higher, the priority for allocating the corresponding tested memory cell to the at least one application is lower.

17. The system of claim 16, wherein a preset number of discontinuous error times is provided and at least two, the number of error times further comprises a number of discontinuous error times, the number of discontinuous error times is counted according to a defect detecting situation which defines that the number of discontinuous error times is accumulatively counted only when the tested memory cell is detected as defective in successive testing procedures; if the tested memory is not detected in one testing procedure, the number of discontinuous error times is reset to zero; and the tested memory allocating regulation further defines that when the number of discontinuous error times of the tested memory cell exceeds the preset number of discontinuous error times, the corresponding tested memory cell is not allowed to be allocated to any application.

18. A non-transient computer-readable medium comprising instructions for allocating at least one tested memory cell of a memory device within a computing system, wherein the memory device comprising a plurality of memory cells and utilized in the computing system; at least one application is executable in the computing system; wherein during at least one memory testing procedure, at least one of the plurality of memory cells is tested to form a tested memory cell, the tested memory cell has a number of error times, the number of error times comprises a total number of error times which records the times that the tested memory cell is detected as defective; when the instructions are executed by at least one processor of the computing system, configure the at least one processor to:
follow a tested memory allocating regulation to allocate tested memory cells to the at least one application; wherein the tested memory allocating regulation defines that when the total number of error times of the tested memory cell is higher, the priority for allocating the corresponding tested memory cell to the at least one application is lower.

19. The non-transient computer-readable medium of claim 18, wherein a preset number of discontinuous error times is provided and at least two, the number of error times further comprises a number of discontinuous error times, the number of discontinuous error times is counted according to a defect detecting situation which defines that the number of discontinuous error times is accumulatively counted only when the tested memory cell is detected as defective in successive testing procedures; if the tested memory is not detected in one testing procedure, the number of discontinuous error times is reset to zero; and the tested memory allocating regulation further defines that when the number of discontinuous error times of the tested memory cell exceeds the preset number of discontinuous error times, the corresponding tested memory cell is not allowed to be allocated to any application.
